(19) United States
(12) Patent Application Publication
(10) Pub. No.: US 2026/0290770 A1
(43) Pub. Date: Sep. 24, 2026

(54) SYSTEMS AND METHODS FOR ACHIEVING UNIFORMITY WITH MULTIPLE COILS

(71) Applicant: Lam Research Corporation, Fremont, CA (US)

(72) Inventors: Hema Swaroop Mopidevi, Georgetown, TX (US); Neil Martin Paul Benjamin, Palo Alto, CA (US); Roger Patrick, Mountain View, CA (US); Lee Chen, Cedar Creek, TX (US); Alexander Miller Paterson, San Jose, CA (US)

(21) Appl. No.: 19/477,473

(22) PCT Filed: Apr. 26, 2024
(86) PCT No.: PCT/US2024/026662

§ 371 Date: Oct. 21, 2025

Related U.S. Application Data
(60) Provisional application No. 63/463,862, filed on May 3, 2023.

(51) Int. Cl. H01J 37/32

(52) U.S. Cl. CPC H01J 37/3299; H01J 37/3211; H01J 37/32146; H01J 37/32155; H01J 37/32183; H01J 37/32954; H01J 2237/334

(57) ABSTRACT

Systems and methods for achieving uniformity are described. One of the systems includes a radio frequency (RF) source system that generates a plurality of RF signals. The system further includes RF antennas that are coupled to the RF source system to receive the plurality of RF signals. The plasma system includes a processor coupled to the RF source system. The processor determines a first parameter from one or more sensor signals received from one or more sensors associated with a first antenna. The processor further determines determine a second parameter from the one or more sensor signals received from the one or more sensors associated with a second antenna. The processor modifies a variable of the RF source system when it is determined that the first or second parameter is outside a predetermined parameter threshold range to achieve the uniformity across a surface of a substrate.

### FIELD

The present embodiments relate to systems and methods for achieving uniformity with multiple coils.

### BACKGROUND

A plasma tool is used to process a wafer to create features in the wafer. The wafer is placed within a plasma chamber. The plasma tool includes a radio frequency (RF) generator, a match, and the plasma chamber. The RF generator is coupled to the match and the match is coupled to the plasma chamber. The RF generator generates an RF signal that is provided to the match. The match matches an impedance of a load coupled to the match with that of a source coupled to the match to modify an impedance of the RF signal.

The RF signal having the modified impedance is output from the match to the plasma chamber. Also, a process gas is supplied to the plasma chamber to process the substrate. However, the substrate is not processed in an accurate manner. For example, features etched within the substrate are not uniform.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for achieving uniformity with multiple coils. It should be appreciated that the present embodiments can be implemented in numerous ways, e.g., a process, an apparatus, a system, a device, or a method on a computer readable medium. Several embodiments are described below.

In one embodiment, a plasma system is described. The plasma system includes a radio frequency (RF) source system that generates a plurality of RF signals. The plasma system further includes a plurality of RF antennas coupled to the RF source system to receive the plurality of RF signals. The plurality of RF antennas includes a first antenna and a second antenna. The plurality of RF antennas generates a plurality of electromagnetic fields within a plasma chamber. The plasma system includes a processor coupled to the RF source system. The processor determines a first parameter from one or more sensor signals received from one or more sensors associated with the first antenna. The processor further determines determine a second parameter from the one or more sensor signals received from the one or more sensors associated with the second antenna. The processor also determines whether the first parameter is within a predetermined parameter threshold range and determines whether the second parameter is within the predetermined parameter threshold range. The processor modifies a variable of the RF source system when it is determined that the first parameter is outside the predetermined parameter threshold range or the second parameter is outside the predetermined parameter threshold range or a combination thereof. The variable is modified to achieve uniformity across a surface of a substrate.

In an embodiment, a plasma system is described. The plasma system includes a plurality of gas sources. The plurality of gas sources includes a first gas source and a second gas source. The first gas source stores a first gas and the second gas source stores a second gas. The plasma system further includes a plurality of valve control systems. The plurality of valve control systems includes a first valve control system and a second valve control system. The plasma system includes a plurality of valves, such as a first valve and a second valve. The first valve is coupled to the first valve control system and to the first gas source and the second valve is coupled to the second valve control system and to the second gas source. The plasma system includes a plurality of RF antennas that receive a plurality of RF signals. The plurality of RF antennas includes a first antenna and a second antenna. The plurality of RF antennas generates a plurality of electromagnetic fields within a plasma chamber. The plasma system includes a processor coupled to the plurality of valve control systems. The processor determines a first parameter from one or more sensor signals received from one or more sensors associated with the first antenna. The processor also determines a second parameter from the one or more sensor signals received from the one or more sensors associated with the second antenna. The processor further determines whether the first parameter is within a predetermined parameter threshold range and determines whether the second parameter is within the predetermined parameter threshold range. The processor modifies one or more flow rates of one or more of the first and second gases when it is determined that the first parameter is outside the predetermined parameter threshold range or the second parameter is outside the predetermined parameter threshold range or a combination thereof.

In an embodiment, a plasma system includes a plasma chamber. The plasma system further includes an RF source system that generates a plurality of RF signals. The plasma system includes a plurality of RF antennas coupled to the RF source system to receive the plurality of RF signals. The plurality of RF antennas includes a first antenna and a second antenna. The plurality of RF antennas generates a plurality of electromagnetic fields within the plasma chamber. The plasma system includes a plurality of gas sources including a first gas source and a second gas source. The first gas source stores a first gas and the second gas source stores a second gas. The plasma system has a plurality of valve control systems. The plurality of valve control systems includes a first valve control system and a second valve control system. The plasma system includes a plurality of valves, such as a first valve and a second valve. The first valve is coupled to the first valve control system and to the first gas source and the second valve is coupled to the second valve control system and to the second gas source. The plasma system includes a processor coupled to the RF source system and to the plurality of valve control systems. The processor determines a first parameter from one or more sensor signals received from one or more sensors associated with the first antenna and determines a second parameter from the one or more sensor signals received from the one or more sensors associated with the second antenna. The processor further determines whether the first parameter is within a predetermined parameter threshold range and determines whether the second parameter is within the predetermined parameter threshold range. The processor modifies a variable of the RF source system or one or more flow rates of one or more of the first and second gases or a combination thereof when it is determined that one of the first and second parameters is outside the predetermined parameter threshold range. The variable or the one or more flow rates or the combination thereof is modified to achieve uniformity across a surface of a substrate.

Several advantages of the herein described systems and methods include achieving uniformity in processing the substrate when multiple coils are used. When the multiple coils are used, one or more sensor signals providing an indication of one or more parameters, such as electron temperature or plasma density, are received from one or more sensors associated with one or more regions within a plasma chamber. Based on the one or more parameters, a processor controls an RF source system to control one or more variables, such as power and frequency, of one or more RF signals generated by the RF source system or controls one or more valve control systems to control one or more flow rates of one or more gases that flow into the plasma chamber to achieve the uniformity. By controlling the one or more variables or the one or more flow rates associated with the one or more regions, the uniformity across a top surface of a substrate is achieved. When the uniformity is achieved, plasma instability across the top surface of the substrate is reduced and the substrate is processed in a uniform manner.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1A is a diagram of an embodiment of a system to illustrate an achievement in uniformity across a top surface of a substrate.

FIG. 1B is a top view of an embodiment of a system to illustrate positions of multiple sensors with respect to multiple coils.

FIG. 1C is a diagram of an embodiment of a system to illustrate a control of one or more gas flows of one or more process gases into a plasma chamber.

FIG. 1D is a diagram of an embodiment of a host computer to illustrate a control of a radio frequency (RF) source system or one or more flow rates of one or more of the process gases into the plasma chamber or a combination thereof.

FIG. 2A is a diagram of an embodiment of a system to illustrate determination and application of one or more parameters of one or more of RF signals in real-time.

FIG. 2B is a diagram of an embodiment of a system to illustrate that a substrate is not processed in real-time based on one or more of sensor signals.

FIG. 3A is a diagram of an embodiment of a system to illustrate an application of a scanning sensor.

FIG. 3B is a diagram of an embodiment of a system to illustrate use of the scanning sensor to achieve uniformity across the top surface of the substrate.

FIG. 4A is a diagram of an embodiment of a system to illustrate learning by an artificial intelligence (AI) model of signal-to-noise ratios (SNRs) associated with different regions within an inside volume of the plasma chamber.

FIG. 4B is a diagram of an embodiment of a system to illustrate an application of an artificial intelligence (AI) model to determine whether to apply a value of a sensor signal received from any of the sensors to determine whether to control the RF source system or one or more of multiple valves to achieve the uniformity across the top surface of the substrate.

### DETAILED DESCRIPTION

The following embodiments describe systems and methods for achieving uniformity across a top surface of a substrate with multiple coils. It will be apparent that the present embodiments may be practiced without some or all of these specific details. In other instances, well known operations have not been described in detail in order not to unnecessarily obscure the present embodiments.

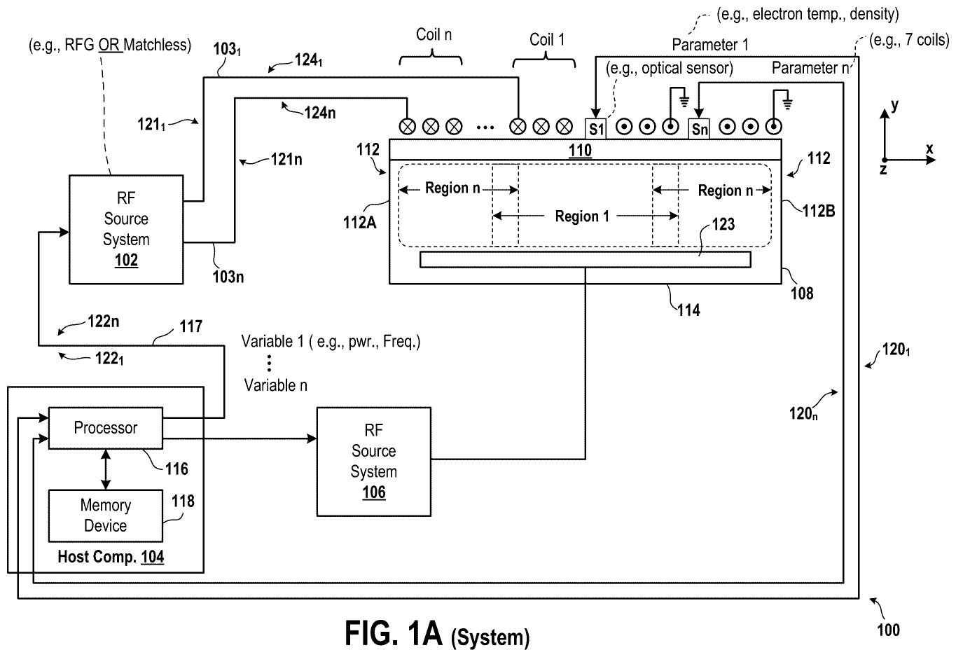

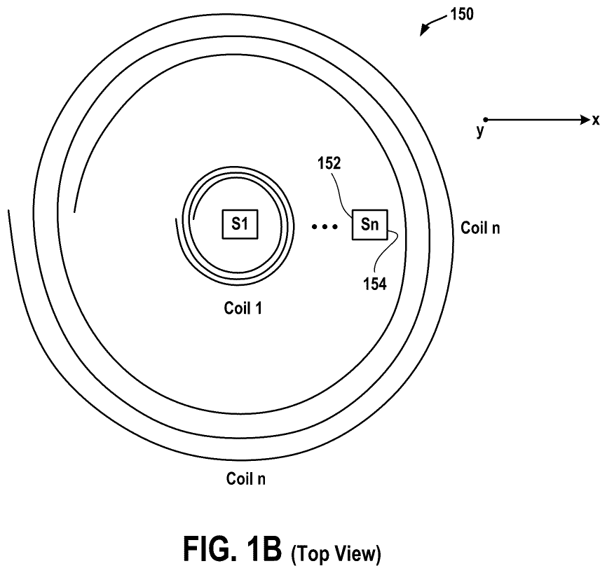

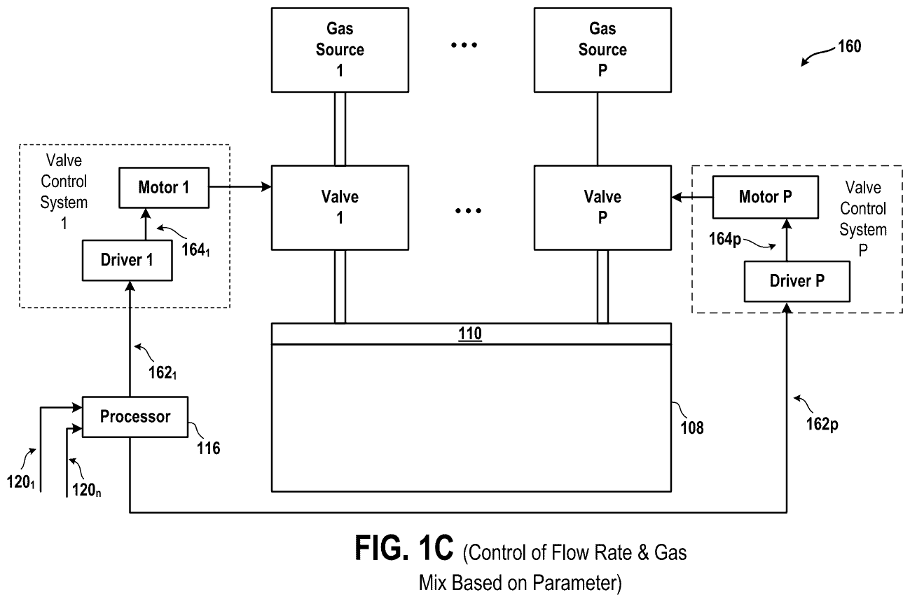

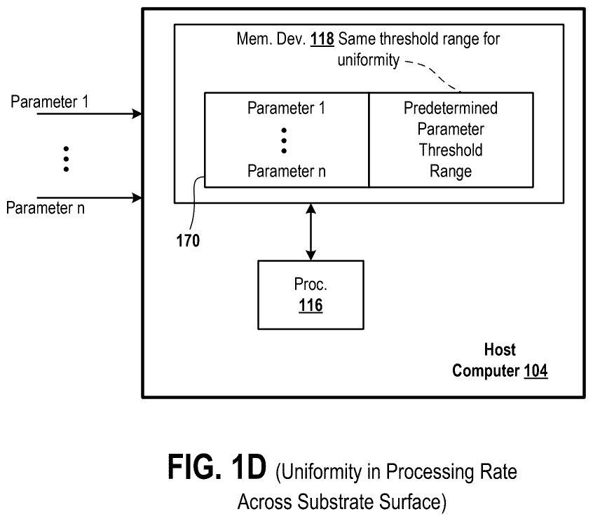

FIG. 1A is a diagram of an embodiment of a system 100 to illustrate an achievement in uniformity across the top surface of the substrate. An example of the uniformity is a similarity in plasma impedance across the top surface of the substrate. To illustrate, the plasma impedance is similar when the plasma impedance is within a predetermined impedance range. As another example, the uniformity includes similarity in a processing rate across the top surface of the substrate. In the example, the uniformity in the processing rate includes a similarity in etch rates or deposition rates of features of the substrate. To illustrate, the similarity in the etch rates is achieved when depths of the features are within a preset depth range. As another illustration, the similarity in the deposition rates is achieved when horizontal levels of a material deposited across the top surface are within a preset horizontal level range. The system 100 includes a radio frequency (RF) source system 102, a host computer 104, another RF source system 106, and a plasma chamber 108.

An example of an RF source system includes one or more RF generators and one or more impedance matching circuits. To illustrate, the one or more RF generators include a first RF generator and so on until an n^{th} RF generator, and the one or more impedance matching circuits include a first impedance matching circuit and so on until an n^{th} impedance matching circuit, where n is a positive integer. The first impedance matching circuit is coupled to the first RF generator via a first RF cable and the n^{th} impedance matching circuit is coupled to the n^{th} RF generator via an n^{th} RF cable.

An RF generator generates a sinusoidal RF signal, which is sent via an RF cable to an impedance matching circuit coupled to the RF generator. The impedance matching circuit matches an impedance of a load, such as the plasma chamber 108, coupled to an output of the impedance matching circuit with an impedance of a source, such as the RF generator, coupled to an input of the impedance matching circuit to modify an impedance of the sinusoidal RF signal to output a modified RF signal, which is also a sinusoidal signal.

Another example of an RF source system includes one or more matchless plasma sources, such as a first matchless plasma source and so on until an n^{th} matchless plasma source, and one or more reactive circuits, such as a first reactive circuit and so on until an n^{th} reactive circuit. A matchless plasma source includes a controller, an RF frequency source, a drive circuit, an amplification circuit, and a direct current (DC) rail. Also, the matchless plasma source excludes an impedance matching circuit and excludes a 50-ohm RF cable. To illustrate, the controller is coupled to the RF frequency source, which is coupled to the drive circuit. The drive circuit is coupled to the amplification circuit, which is coupled to a reactive circuit. Also, the controller is coupled to the DC rail, which is coupled to the amplification circuit. The controller controls the RF frequency source to output a square wave signal having a radio frequency. The gate driver outputs two square wave signals, in reverse synchronization with each other, based on the square wave signal output from the RF frequency source. Also, the controller controls the DC rail to output a DC voltage, which is supplied to the amplification circuit. Based on the DC voltage and the square wave signals output from the gate driver, the amplification circuit outputs an amplification waveform, which is a digital pulsed signal. The reactive circuit removes harmonics from the digital pulse signal to output a sinusoidal RF waveform.

An example of a controller, as used herein, includes one or more processors and one or more memory devices. The one or more processors of the controller are coupled to the one or more memory devices of the controller. As an example, a processor, as used herein, is an application specific integrated circuit (ASIC), or a central processing unit (CPU), or a field programmable gate array (FPGA), a programmable logic device (PLD), or a microprocessor. Examples of a memory device, as used herein, include a read-only memory (ROM) and a random access memory (RAM). To illustrate, the memory device is a flash memory or a redundant array of independent discs (RAID).

The plasma chamber 108 includes a dielectric window 110 and a sidewall 112, which includes a left sidewall portion 112A and a right sidewall portion 112B. The plasma chamber 108 further includes a substrate support 123, such as an electrostatic chuck (ESC). The top surface of the substrate does not face the substrate support 123 of a plasma chamber 108 but faces a gap between the substrate support 123 and the dielectric window 110 of the plasma chamber 108. A bottom surface of the substrate is placed on the substrate support 123 to be adjacent to the substrate support 123. Also, the plasma chamber 108 includes a bottom wall 114. The dielectric window 110 forms a top wall of the plasma chamber 108.

The plasma chamber 108 is associated with multiple coils, such as a coil 1 and a coil n. For example, n is 7 when seven coils are associated with the plasma chamber 108. As another example, n is three when three coils are associated with the plasma chamber 108. As an example, a coil associated with the plasma chamber 108 when the coil is located besides a wall of the plasma chamber 108 to generate an electromagnetic field within an inside volume of the plasma chamber 108. To illustrate, each coil 1 and n is associated with the plasma chamber 108 when the coil is located above and adjacent to the top wall of the plasma chamber 108. As another example, a coil is associated with the plasma chamber 108 when the coil is located adjacent to the side wall 112 to surround the side wall 112 to generate an electromagnetic field within an inside volume of the plasma chamber 108. As yet another example, a coil is associated with the plasma chamber 108 when the coil is located adjacent to a sidewall portion, such as the sidewall portion 112A or 112B, of the plasma chamber 108 to generate an electromagnetic field within the inside volume of the plasma chamber 108. To illustrate, a coil is associated with the plasma chamber 108 when the coil is located to the right of the right side wall portion 112B or to the left of the left side wall portion 112A.

Also associated with the plasma chamber 108 are multiple sensors S1 through Sn, where n is the positive integer. For example, each sensor S1 through Sn has a probe, such as a tip, that extends into the plasma formed within the plasma chamber 108. As another example, each sensor S1 through Sn is attached to a top surface of the dielectric window 110. As yet another example, each sensor S1 through Sn is a part of multiple beam scanning antennas, such as a phased array antenna that can electronically scan regions 1 and n of plasma at microwave frequencies, or a reflect array antenna, or a parasitic beam steering antenna array. In the example, the sensors S1 through Sn are not mechanically moved across one or more of the regions 1 through n.

A number of the sensors S1 through Sn is equal to a number of the coils 1 through n. Examples of a sensor include an electron temperature sensor, a ultra high frequency (UHF) sensor, a plasma density sensor, a planar ion flux probe, a hotwire, an optical sensor, a microwave sensor, a resonant hair pin antenna, a probe, and an antenna sensor. An example of the electron temperature sensor includes a thermocouple. An example of the plasma density sensor includes a Langmuir probe. To illustrate, a metal probe is directly exposed in plasma formed within the plasma chamber 108, a direct current bias voltage is applied to the metal probe, and based on a current value flowing through the metal probe per unit of time, density of the plasma is measured. As yet another example, the microwave sensor includes a microwave source antenna and a microwave receiver. The plasma chamber 108 is provided with windows which are opposed to each other with the plasma positioned therebetween. A microwave, such as a wave with frequency in a gigahertz (GHz) range, is radiated from the microwave source antenna via one of the windows, the plasma, and another one of the windows to the microwave receiver. The plasma density is determined based on phase contrast between the radiated microwave and microwave detected by the microwave receiver. The microwave sensor includes the microwave source and the microwave receiver.

The host computer 104 includes a processor 116 and a memory device 118. The processor 116 is coupled to the memory device 118. The dielectric window 110 is located above and faces the substrate support 123 to form the gap between the dielectric window and the substrate support 123. The dielectric window 110, the side wall 112, and the bottom wall 114 enclose the inside volume of the plasma chamber 108.

Each coil 1 through n has multiple turns. For example, each coil 1 through n has three turns. To illustrate, turns of a coil are concentric and are in the same horizontal plane. As another illustration, at least one turn of a coil is located in a different horizontal plane than a horizontal plane in which remaining turns of the coil are located, and the turns of the coil are not concentric. A horizontal plane lies along, such as parallel to, an x-axis and lies along a z-axis. The x-axis is perpendicular to a y-axis and the z-axis, and the y-axis is perpendicular to the z-axis,

The coil 1 surrounds the sensor S1. For example, multiple turns of the coil 1 are located around the sensor S1 to encircle the sensor S1. Also, the sensor Sn is located between the coils 1 and n. For example, an outermost turn of the coil 1 is adjacent to the sensor Sn and an innermost turn of the coil n is adjacent to the sensor Sn.

It should be noted that a coil is an example of an RF antenna. For example, the RF antenna can have a circular shape of each turn or a shape other than the circular shape of each turn. To illustrate, each turn of the RF antenna is hexagonal in shape or octagonal in shape or square in shape. The coil has turns that are circular in shape. As such, instead of the coil 1, a first RF antenna is used and instead of the coil n, an n^{th} RF antenna is used.

The processor 116 is coupled to the RF source system 102 via a connection 117. For example, the processor 116 is coupled via a first transfer cable to the first RF generator of the RF source system 102 and via an n^{th} transfer cable to the n^{th} RF generator of the RF source system 102, where n is a positive integer. As another example, the processor 116 is coupled to a first matchless plasma source of the RF source system 102 and to an n^{th} matchless plasma source of the RF source system 102. Example of a transfer cable is a communication cable that allows data to be transferred in a serial manner, or in a parallel manner, or via a universal serial bus (USB) protocol.

The RF source system 102 is coupled to the coils 1 through n via RF connections 103₁ through 103ₙ. For example, the first impedance matching circuit of the RF source system 102 is coupled via a first RF transmission line to the coil 1 and the n^{th} impedance matching circuit of the RF source system 102 is coupled via an n^{th} RF transmission line to the coil n. As another example, the first matchless plasma source of the RF source system 102 is coupled via the first reactive circuit to the coil 1 and the n^{th} matchless plasma source of the RF source system 102 is coupled via the n^{th} reactive circuit to the coil n. The first RF transmission line is an example of the RF connection 103₁ and the n^{th} RF transmission line is an example of the RF connection 103ₙ.

The processor 116 is also coupled to the RF source system 106. For example, the processor 116 is coupled to a first RF generator of the RF source system 106 and so on until the processor 116 is coupled to an m^{th} RF generator of the RF source system 106, where m is a positive integer. As another example, the processor 116 is coupled to a first matchless plasma source of the RF source system 106 and so on until the processor 116 is coupled to an m^{th} matchless plasma source of the RF source system 106. As an example, the positive integer n is equal to the positive integer m. As another example, the positive integer n is unequal to the positive integer m.

The RF source system 106 is coupled to the substrate support 123. For example, the first through m^{th} RF generators of the RF source system 106 are coupled to an impedance matching circuit of the RF source system 106 via first through m^{th} RF cables of the RF source system 106, and the impedance matching circuit is coupled via an RF transmission line to the substrate support 123. As another example, a single matchless plasma source of the RF source system 106 is coupled via a reactive circuit of the RF source system 106 to the substrate support 123.

The RF source system 102 generates multiple RF signals 121₁ through 121ₙ, and sends the RF signals 121₁ through 121ₙ via the RF connections 103₁ through 103ₙ to the coils 1 through n. For example, the RF signal 1211 is sent via the RF connection 103₁ to the coil 1 and the RF signal 121ₙ is sent via the RF connection 103ₙ to the coil n. Upon receiving the RF signals 121₁ through 121ₙ, the coils 1 through n generate electromagnetic fields. For example, upon receiving the RF signal 121₁, the coil 1 generates a first electromagnetic field and upon receiving the RF signal 121ₙ, the coil n generates an n^{th} electromagnetic field. In addition to the RF signals 121₁ through 121ₙ, one or more process gases, described further below, are supplied to the inside volume of the plasma chamber 108. The first through n^{th} electromagnetic fields interact with the one or more process gases to strike or maintain plasma within the inside volume of the plasma chamber 108.

When the first through n^{th} electromagnetic fields are generated based on the RF signals 121₁ through 121ₙ, each of the sensors S1 through Sn senses a factor, such as temperature or flux, of plasma formed within the inside volume of the plasma chamber 108 to output a respective sensor signal. For example, the sensor S1 senses the factor of the region 1 having plasma formed within the inside volume of the plasma chamber 108 to generate a sensor signal 120₁ and the sensor Sn senses the factor of the region n having plasma formed within the inside volume of the plasma chamber 108 to generate a sensor signal 120ₙ. To illustrate, a major portion of the region 1 is located below the coil 1 and a major portion of the region n is located below the coil n. In the illustration, no portion or a minor portion of the region 1 is located below the coil n and no portion or a minor portion of the region n is located below the coil 1. As another example, each sensor S1 through Sn is an antenna to form the phased array of antennas. In the example, each sensor S1 through Sn is coupled to a respective phase shifter, and the phase shifters are coupled to the processor 116. Also, in the example, each of the phase shifters is coupled to a transmitter, such as an RF transmitter. Further, in the example, the RF transmitter sends an RF current to the antennas via the phase shifters. In the example, the processor 116 sends a signal to each of the phase shifters to modify a phase of a respective portion of the RF current that is to be received by a respective one of the antennas. In the example, the phase is modified to control directions of beams that are output from the antennas based on the RF current. In the example, when the directions of beams are controlled, the beams are electronically steered. Further, in the example, each of the antennas includes a digital receiver and the factor is sensed by the antennas to output a respective one of the sensors signals sensor signals 120₁ through 120ₙ. When the phases of the portions of the RF current are controlled by the processor 116, the sensors S1 through Sn are electronically controlled by the processor 116.

Impedance of plasma in the region 1 is created and affected by the first electromagnetic field generated based on the RF signal 121₁ and impedance of plasma in the region n is created and affected by the n^{th} electromagnetic field generated based on the RF signal 121ₙ. The first electromagnetic field extends in radial and azimuthal directions across the region 1 and the n^{th} electromagnetic field also extends in radial and azimuthal directions across the region n.

The sensor signals 120₁ through 120ₙ are sent from the sensors S1 through Sn to the processor 116. Upon receiving the sensor signals 120₁ through 120ₙ, the processor 116 determines parameters from the factors identified by the sensor signals 120₁ through 120ₙ. For example, when the sensor signals 120₁ through 120ₙ indicate the temperatures of the regions 1 through n having plasma within the plasma chamber 108, the processor 116 identifies the temperatures to be the parameters. To illustrate, the processor 116 identifies the temperature of plasma, such as temperature of electrons, within the region 1 from the sensor signal 120₁ and identifies the temperature of plasma, such as temperature of electrons, within the region n from the sensor signal 120ₙ. As another example, when the sensor signals 120₁ through 120ₙ indicate ion flux of plasma within the regions 1 through n having plasma formed within the inside volume of the plasma chamber 108, the processor 108 calculates plasma density within each of the regions 1 through n from a respective one of the sensor signals 120₁ through 120ₙ. As an illustration, the processor 108 calculates the density of plasma within the region 1 as an exponential constant of a ratio of a first term and second term. In the illustration, the first term is potential energy of an electron. Further, in the illustration, the second term is the temperature of plasma within the region 1. In the illustration, the potential energy of the electron is received from a user via an input device. The input device is coupled to the processor 108. As another illustration, the processor 108 calculates the density of plasma within the region 1 as a function of the ion flux, a fundamental charge q, a temperature Te of an electron of the plasma within the plasma chamber 108, and ion mass Mi. To further illustrate, the density within the region 1 is calculated as a ratio of the ion flux within the region 1 and a first product of the fundamental charge and a first term. The first term is a square root of a ratio of a second term and a third term. The second term is a product of the electron temperature Te within the region 1 and a Boltzmann constant k and the third term is the ion mass Mi. The ion mass Mi is received from the user via the input device that is coupled to the processor 116. Examples of the parameters include electron temperature of plasma, such as electrons of plasma, within the plasma chamber 108 and plasma density of the plasma. Examples of the input device include a mouse, a keypad, a keyboard, a stylus, a touchscreen, and a touchpad.

The gas sources 1 through p supply first through p^{th} process gases via respective lines to a respective one of the valves 1 through p. For example, the gas source 1 supplies the first process gas via a first line to the valve 1 and the gas source p supplies the p^{th} process gas via a p^{th} line to the valve p. Examples of a process gas include an oxygen-containing gas, a nitrogen-containing gas, and a chlorine-containing gas. To illustrate, the first process gas is the oxygen-containing gas and the p^{th} process gas is the nitrogen-containing gas. To further illustrate, at least one chemical element of the first process gas is different from at least chemical element of the p^{th} process gas. As another further illustration, the first process gas is a mixture of Chlorine (Cl₂) and Boron Trichloride (BCl₃) and the p^{th} process gas is a mixture of Cl₂ and nitrogen (N₂).

The processor 116 generates one or more control signals 122₁ through 122ₙ to control the RF source system 102 based on one or more of the parameters determined from one or more of the sensor signals 120₁ through 120ₙ. For example, the processor 116 generates the control signal 122₁ based on one or more of the parameters of one or more of the sensor signals 120₁ based on one or more through 120ₙ and generates the control signal 122ₙ based on one or more of the parameters of one or more of the sensor signals 120₁ through 120ₙ. Details of generation of the control signals 122₁ through 122ₙ are provided below.

The processor 116 sends the one or more control signals 122₁ through 122ₙ via the connection 117 to the RF source system 102. For example, the processor 116 sends the control signal 122₁ via the first transfer cable to the first RF generator of the RF source system 102 to control a variable of the first RF generator of the RF source system 102 and sends the control signal 122ₙ via the n^{th} transfer cable to the n^{th} RF generator of the RF source system 102 to control the variable of the n^{th} RF generator of the RF source system 102. To illustrate, the processor 116 sends the control signal 122₁ indicating a frequency or power or both the frequency and power of an RF signal 124₁ to be generated by the first RF generator of the RF source system 102. Also, the processor 116 sends the control signal 122ₙ indicating a frequency or power or both the frequency and power of an RF signal 124ₙ to be generated by the n^{th} RF generator of the RF source system 102.

As another example, the processor 116 sends the control signal 122₁ via the first transfer cable to the first matchless plasma source of the RF source system 102 to control the variable of the first matchless plasma source of the RF source system 102 and sends the control signal 122ₙ via the n^{th} transfer cable to the n^{th} matchless plasma source of the RF source system 102 to control the variable of the n^{th} matchless plasma source of the RF source system 102. To illustrate, the processor 116 sends the control signal 122₁ indicating a frequency or power or both the frequency and power of the RF signal 124₁ to be generated by the first matchless plasma source of the RF source system 102. Also, the processor 116 sends the control signal 122ₙ indicating a frequency or power or both the frequency and power of the RF signal 124ₙ to be generated by the n^{th} matchless plasma source of the RF source system 102. Examples of the variable include frequency and power.

The RF signal 124₁ is sent from the RF source system 102 via the RF connection 103₁ to the coil 1 and the RF signal 124ₙ is sent from the RF source system 102 via the RF connection 103ₙ to the coil n. Based on one or more of the powers and one or more of the frequencies of one or more of the RF signals 124₁ through 124ₙ, one or more of the first through n^{th} electromagnetic fields generated by the coils 1 through n based on the RF signals 121₁ through 121ₙ is modified. For example, impedance of plasma within the region 1 affected by the first electromagnetic field generated based on the RF signal 124₁ is modified and impedance of plasma within the region n affected by the n^{th} electromagnetic field generated based on the RF signal 124ₙ is modified.

The processor 116 sends one or more of the control signals 122₁ through 122ₙ to the RF source system 102 based on the parameters determined from the sensor signals 120₁ through 120ₙ until the processor 116 determines that the parameters determined from the sensor signals 120₁ through 120ₙ are within the predetermined parameter threshold range. Upon determining so, the processor 116 does not further control the RF source system 102. For example, the processor 116 stops sending one or more of the control signals 122₁ through 122ₙ to the RF source system 102 for modifying the one or more variables of the one or more RF signals 124₁ and RF signal 124ₙ.

In an embodiment, the substrate support 123 is coupled to a ground potential instead of being coupled to the RF source system 106.

FIG. 1B is a top view of an embodiment of a system 150 to illustrate positions of the sensors S1 through Sn with respect to the coils 1 through n. The system 150 includes the sensors S1 through Sn and the coils 1 through n. As shown, the sensor S1 is associated with the coil 1. For example, the sensor S1 is surrounded by multiple turns of the coil 1 located in a horizontal plane, which is formed between the x and y-axes. To illustrate, the sensor S1 is located in the same horizontal plane as that of the coil 1. As another illustration, the sensor S1 is located in a different horizontal plane from that of the coil 1. Also, the sensor Sn is associated with the coil n. For example, the sensor Sn is located between the coils 1 and n. To illustrate, the sensor Sn is surrounded by the turns of the coil 1 on one side 152 of the sensor Sn and is surrounded by the turns of the coil n on an opposite side 154 of the sensor Sn. In the illustration, the side 152 faces the coil 1 and the side 154 faces the coil n. Further, in the illustration, the side 152 faces a horizontal direction opposite to a horizontal direction in which the side 154 is facing. In the illustration, the horizontal direction is along the x-axis. Also, in the illustration, the sensors S1 and Sn and the coil 1 are located in the same horizontal plane. As another illustration, the sensor Sn is located in a different horizontal plane than one or more horizontal planes in which one or more of the coils 1 and n are located.

The coil n surrounds the coil 1. For example, an innermost turn of the coil n has a larger diameter or perimeter compared to an outermost turn of the coil 1 and the coils 1 and n are located in the same horizontal plane. As another example, an innermost turn of the coil n has a larger diameter or perimeter compared to an outermost turn of the coil 1 and the coils 1 and n are located in different horizontal planes.

FIG. 1C is a diagram of an embodiment of a system 160 to illustrate a control of one or more gas flows of one or more of the process gases into the plasma chamber 108. The system 160 includes multiple gas sources 1 through p, where p is a positive integer. The system 160 further includes multiple valves 1 through p, multiple motors 1 through p, and multiple drivers 1 through p. The system 160 includes the processor 116 and the plasma chamber 108. An example of a gas source includes a gas storage, such as a gas container or a gas box. An example of a motor is an electric motor. An example of a driver includes one or more transistors.

The processor 116 is coupled to the drivers 1 through p. Each driver 1 through p is coupled to a respective one of the motors 1 through p. For example, the driver 1 of a valve control system 1 is coupled to the motor 1 of the valve control system 1 and the driver p of a valve control system p is coupled to the motor p of the valve control system p. Each motor 1 through p is coupled to a respective one of the valves 1 through p. For example, the motor 1 is coupled to the valve 1 and the motor p is coupled to the valve p. Each gas source 1 through p is coupled to a respective one of the valves 1 through p. For example, the gas source 1 is coupled to the valve 1 via a gas line and the gas source p is coupled to the valve p via a gas line. Each valve 1 through p is coupled via the dielectric window 110 to the inside volume of the plasma chamber 108.

The processor 108 generates one or more control signals 162₁ through 162ₚ based on the one or more parameters. The one or more parameters are determined by the processor 108 based on one or more of the sensor signals 120₁ through 120ₙ. The processor 108 sends the control signal 162₁ to the driver 1 and the control signal 162ₚ to the driver p. Upon receiving the control signals 162₁ through 162ₚ, the drivers 1 through p generate drive signals 164₁through 164ₚ, such as current signals, based on the control signals 162₁ through 162ₚ, and send the drive signals 164₁ through 164ₚ to the motors 1 through p. For example, the drive signal 164₁ generated by the driver 1 is sent to the motor 1 and the drive signal 164ₚ generated by the driver p is sent to the motor p. In response to receiving the drive signals 164₁ through 164ₚ, the motors 1 through p operate. For example, the motor 1 operates, such as rotates, upon receiving the drive signal 1 and the motor p operates in response to the drive signal p. Also, each of the valves 1 through p operates, such as opens, partially opens, or closes when a response one of the motors 1 through p operates. For example, when the motor 1 operates, the valve 1 operates, such as opens or partially opens or closes, and when the motor p operates, the valve p opens or partially opens or closes to operate.

Each of the valves 1 through p operates to control a flow rate, such as to allow or partially allow or disallow a flow, of a respective one of the first through pth process gases from a respective one of the gas sources 1 through p into the inside volume of the plasma chamber 108. For example, the valve 1 opens to allow a flow of the first process gas from the gas source 1 to the inside volume of the plasma chamber 108 and the valve p closes to disallow a flow of the p^{th} process gas from the gas source p to the inside volume of the plasma chamber 108. As another example, the valve 1 partially opens to partially allow a flow of the first process gas from the gas source 1 to the inside volume of the plasma chamber 108 and the valve p opens to allow a flow of the p^{th} process gas from the gas source p to the inside volume of the plasma chamber 108.

FIG. 1D is a diagram of an embodiment of the host computer 104 to illustrate a control of the RF source system 102 (FIG. 1A) or one or more flow rates of one or more of the process gases into the plasma chamber 108 (FIG. 1A) or a combination thereof. The memory device 118 includes a table 170 that stores a list of the parameters, such as a parameter 1 through a parameter n, determined from the sensor signals 120₁ through 120ₙ, and a predetermined parameter threshold range. For example, the parameter 1 is determined by the processor 116 from the factor indicated by the sensor signal 120₁ and the parameter n is determined by the processor 116 from the factor indicated by the sensor signal 120ₙ.

The processor 116 compares each of the parameters 1 through n with the predetermined parameter threshold range to determine whether each of the parameters 1 through n is within the predetermined parameter threshold range. Upon determining that all of the parameters 1 through n are within the predetermined parameter threshold range, the processor 116 does not control the RF source system 102 to modify the variables of the RF signals 121₁ through 121ₙ, and the RF signals 124₁ through 124ₙ (FIG. 1A) are not generated. Also, upon determining that all of the parameters 1 through n are within the predetermined parameter threshold range, the processor 116 does not control the valves 1 through p (FIG. 1C) to control the flow rates of the process gases 1 through p.

On the other hand, upon determining that one or more of the parameters 1 through n is outside the predetermined parameter threshold range, the processor 116 controls the RF source system 102 to modify one or more variables of one or more of the RF signals 121₁ through 121ₙ to generate one or more of the RF signals 124₁ through RF signal 124ₙ or controls one or more of the flow rates of one or more of the first through p^{th} process gases into the plasma chamber 108 or controls the RF source system 102 and the one or more of the flow rates. For example, the processor 116 controls the variable of the first RF generator or the first matchless plasma source of the RF source system 102 to modify the variable of the RF signal 121₁ to generate the RF signal 124₁. In the example, the processor 116 does not control the variable of the n^{th} RF generator or the n^{th} matchless plasma source of the RF source system 102, the variable of the RF signal 121ₙ is not modified, and the RF signal 124₁ is not generated. As another example, the processor 116 controls the valve control system 1 to operate the valve 1 (FIG. 1C) to control, such as increase or decrease, the flow rate of the first process gas from the gas source 1 into the inside volume of the plasma chamber 108. In the example, the processor 116 does not control the valve control system p, the valve p (FIG. 1C) is not operated, and the flow rate of the p^{th} process gas from the gas source p into the inside volume of the plasma chamber 108 is not controlled. As yet another example, the processor 116 controls the first RF generator or the first matchless plasma source and the valve 1 without controlling the n^{th} RF generator or the n^{th} matchless plasma source and the p^{th} flow rate. As yet another example, the processor 116 controls the variable of the n^{th} RF generator or the n^{th} matchless plasma source of the RF source system 102 to modify the variable of the RF signal 121ₙ to generate the RF signal 124ₙ. As still another example, the processor 116 controls the valve control system p to operate the valve p (FIG. 1C) to further control the flow rate of the p^{th} process gas from the gas source p into the inside volume of the plasma chamber 108. As another example, the processor 116 controls the n^{th} RF generator or the n^{th} matchless plasma source and the valve control system p. The processor 116 continues to control one or more of the first through n^{th} RF generators or one or more of the first through n^{th} matchless plasma sources of the RF source system 102 or the one or more of the flow rates of one or more of the first through p^{th} process gases or a combination thereof until all of the parameters 1 through n are within the predetermined parameter threshold range. The predetermined parameter threshold is received by the processor 116 from the user via the input device.

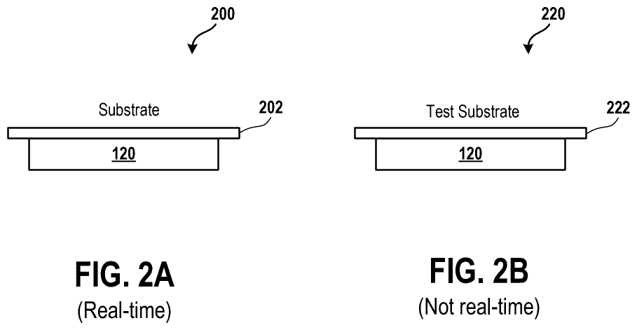

FIG. 2A is a diagram of an embodiment of a system 200 to illustrate determination and application of one or more of the parameters of one or more of the RF signals 124₁ through 124ₙ (FIG. 1A) in real-time. The system 202 includes a substrate 202, such as a semiconductor wafer, and the substrate support 123. The substrate 202, is placed on a top surface of the substrate support 123 for processing. Examples of processing the substrate 202 include etching the substrate 202, depositing one or more materials on the substrate 202, cleaning the substrate 202, and sputtering the substrate 202. The RF signals 121₁ through 121ₙ are generated by the RF source system 102 (FIG. 1A) during a time period in which the substrate 202 is placed on the substrate support 123. Based on the one or more of the sensor signals 120₁ through 120ₙ (FIG. 1A), the processor 116 determines one or more of the parameters. The processor 116 controls the RF source system 102 to modify one or more of the variables of the RF source system 102 or controls one or more of the valves 1 through p (FIG. 1C) to modify one or more of the flow rates of one or more of the process gases 1 through p (FIG. 1C) or a combination thereof based on the one or more of the parameters until the parameters lie within the predetermined parameter threshold range. The RF signals 124₁ through 124ₙ are generated by the RF source system 102 when the parameters lie within the predetermined parameter threshold range and while the substrate 202 is placed on top of the substrate support 123. One or more of the electromagnetic fields in one or more of the regions 1 through n (FIG. 1A) are modified according to the one or more variables of one or more of the RF signals 124₁ through 124ₙ. The one or more of the electromagnetic fields that are modified are applied to the inside volume of the plasma chamber 108 (FIG. 1A) to modify one or more impedances of plasma within one or more of the regions 1 through n. One or more of the modified impedances of plasma within one or more of the regions 1 through n are used to process the substrate 202. As such, by placing the substrate 202 for receiving the sensor signals 120₁ through 120ₙ, determining the one or more parameters based on one or more of the sensor signals 120₁ through 120ₙ, and controlling the RF source system 102 or one or more of the flow rates of one or more of the process gases 1 through p or a combination thereof until the parameters lie within the predetermined parameter threshold range, the uniformity across a top surface of the substrate 202 is achieved in real-time.

FIG. 2B is a diagram of an embodiment of a system 220 to illustrate that the substrate 202 (FIG. 2A) is not processed in real-time based on one or more of the sensor signals 120₁ through 120ₙ (FIG. 1A). The system 220 includes a test substrate 222 and the substrate support 123. An example of the test substrate 222 is a wafer made from glass instead of a semiconductor. Instead of the substrate 202, the test substrate 222 is placed on the substrate support 123. The RF signals 121₁ through 121ₙ are generated by the RF source system 102 (FIG. 1A) during a time period in which the test substrate 222 is placed on the substrate support 123. Based on the one or more of the sensor signals 120₁ through 120ₙ (FIG. 1A), the processor 116 determines one or more of the parameters. The processor 116 controls the RF source system 102 to modify one or more of the variables of the RF source system 102 or controls one or more of the valves 1 through p to modify one or more of the flow rates of one or more of the process gases 1 through p or a combination thereof based on the one or more of the parameters until the parameters lie within the predetermined parameter threshold range. The RF signals 124₁ through 124ₙ are generated by the RF source system 102 when the parameters lie within the predetermined parameter threshold range and while the test substrate 222 is placed on top of the substrate support 123. One or more of the electromagnetic fields in one or more of the regions 1 through n (FIG. 1A) are modified according to the one or more variables of one or more of the RF signals 124₁ through 124ₙ. The one or more of the electromagnetic fields that are modified are applied to the inside volume of the plasma chamber 108 (FIG. 1A) to modify one or more impedances of plasma within one or more of the regions 1 through n. One or more of the modified impedances of plasma within one or more of the regions 1 through n are used to process the substrate 202.

The test substrate 222 is removed from the plasma chamber 108 and the substrate 202 is placed on the top surface of the substrate support 123. After placing the substrate 202, the processor 116 controls the RF source system 102 to output one or more of the RF signals 124₁ through 124ₙ for which one or more of the parameters are within the predetermined parameter range or one or controls more of the valves 1 through p or a combination thereof for which one or more of the parameters are within the predetermined parameter range or a combination thereof to process the substrate 222. There is no need to obtain the sensor signals 120₁ through 120ₙ after the substrate 202 is placed on the top surface of the substrate support 123. For example, the sensors S1 through Sn (FIG. 1A) are removed from the system 100 to process the substrate 222. As such, by placing the test substrate 222 for receiving the sensor signals 120₁ through 120ₙ, determining the one or more parameters based on one or more of the sensor signals 120₁ through 120ₙ, controlling one or more variables of the RF source system 102 or one or more of the flow rates of one or more of the process gases 1 through p or a combination thereof until the parameters lie within the predetermined parameter threshold range, and applying the one or more variables or the one or more flow rates or the combination thereof to process the substrate 222, the uniformity across the top surface of the substrate 222 is achieved but not in real-time.

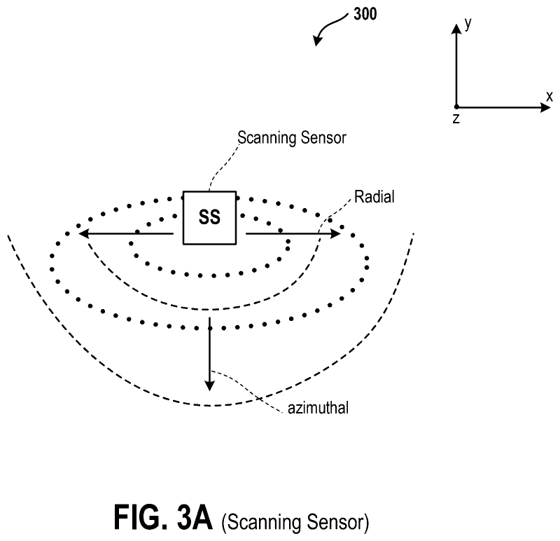

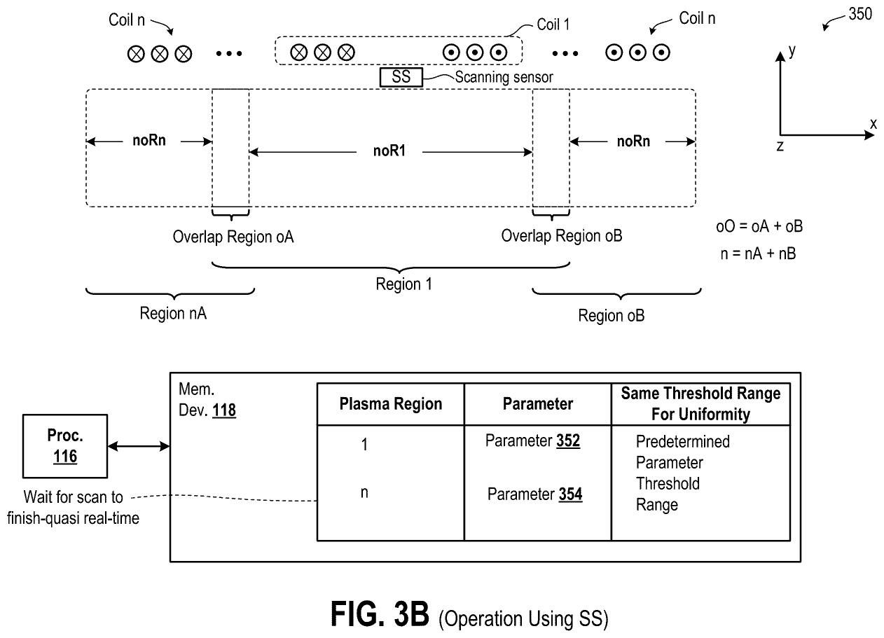

FIG. 3A is a diagram of an embodiment of a system 300 to illustrate an application of a scanning sensor SS, such as a spectrometer. The scanning sensor SS scans one or more of the regions 1 through n (FIG. 1A) within the inside volume of the plasma chamber 108 (FIG. 1A) in multiple directions, such as in a radial direction along the x-axis or the z-axis or along the x and z-axes, and in an azimuthal direction along the y-axis. As an example, the scanning sensor SS is used instead of or in addition to the sensors S1 and Sn (FIG. 1A). In the example, the scanning sensor SS is placed to be at a horizontal level above or below a horizontal level of any of the coils 1 through n to be controlled to move in the radial direction freely without interfering with the coils 1 through n. In the example, the azimuthal direction includes a vertical direction and the radial direction includes the horizontal direction. As another example, the scanning sensor SS is used instead of the sensor S1 and another scanning sensor, such as the scanning sensor SS, is used instead of the sensor Sn. Further, in the example, the scanning sensor SS is placed to be at a horizontal level above or below a horizontal level of any of the coils 1 through n to be controlled to move in the radial direction freely without interfering with any of the coils 1 through n, and the other scanning sensor is placed to be at a horizontal level above or below the horizontal level of any of the coils 1 through n to be controlled to move in the radial direction freely without interfering with any of the coils 1 through n.

The scanning sensor SS has a detector, such as one or more photodiodes or one or charge coupled devices (CCDs), that is controlled by the processor 116 to move to scan in the radial direction or the azimuthal direction or a combination thereof. For example, the processor 116 is coupled to the detector of the scanning sensor SS via a driver and a motor. The driver is coupled to the processor 116 and the motor is coupled to the driver. Also, the motor is coupled to the detector of the scanning sensor SS. The processor 116 sends a control signal to the driver. Based on the control signal, the driver generates a drive signal, such as a current signal, and sends the drive signal to the motor. The motor operates to rotate the detector of the scanning sensor SS in the radial direction to detect the factor along the x axis or the z-axis or a combination thereof or in the azimuthal direction to detect the factor along the y-axis or a combination thereof. When the detector of the scanning sensor SS rotates based on the control signal generated by the processor 116, the scanning sensor SS is mechanically controlled, such as mechanically steered, by the processor 116. As another example, the processor 116 is coupled to a housing, such as a body, of the scanning sensor SS via a driver and a motor. The driver is coupled to the processor 116 and the motor is coupled to the driver. Also, the motor is coupled to the housing of the scanning sensor SS. The processor 116 sends a control signal to the driver. Based on the control signal, the driver generates a drive signal, such as a current signal, and sends the drive signal to the motor. The motor operates to move the housing of the scanning sensor SS in the radial direction to detect the factor along the x axis or the z-axis or a combination thereof or in the azimuthal direction to detect the factor along the y-axis or a combination thereof. When the housing of the scanning sensor SS is moved in the azimuthal direction, the housing of the scanning sensor SS is moved along, such as in a direction parallel to, the side wall 112 (FIG. 1A). When the housing of the scanning sensor SS is used to move in the azimuthal direction, the side wall 112 is a dielectric window. Also, when the housing of the scanning sensor SS is moved in the radial direction, the housing of the scanning sensor SS is moved along, such as in a direction parallel to, the dielectric window 110. It should be noted that movement of the detector of the scanning sensor SS or movement of the housing of the scanning sensor SS is referred to herein as movement of the scanning sensor SS.

FIG. 3B is a diagram of an embodiment of a system 350 to illustrate use of the scanning sensor SS to achieve uniformity across the top surface of the substrate 222 (FIG. 2A). The system 350 includes the coils 1 through n, the scanning sensor SS, the processor 116, and the memory device 118. The coils 1 through n are located at a first horizontal level of a horizontal plane and the scanning sensor SS is located in a second horizontal level, which is below the first horizontal level.

The inside volume of the plasma chamber 108 (FIG. 1A) in which the plasma is formed includes the region 1 and the region n. The region n is formed of a region nA and a region nB. For example, the region nA is a portion of the inside volume radially outward in a negative x direction from the coil 1 and the region nB is a portion of the inside volume radially outward in a positive x direction from the coil 1. Each of the positive x direction and the negative x direction is along the x-axis. Also, the positive x direction is opposite to the negative x direction. The region nA overlaps with the region 1 to form an overlap region oA and the region nB overlaps with the region 1 to form another overlap region oB. A combination of the overlap regions oA and oB is an overlap region oO. The region 1 excluding the overlap region oO is sometimes referred to herein as a nonoverlap region noR1. Also, the region n excluding the overlap region oO is sometimes referred to herein as a nonoverlap region noRn.

The processor 116 controls the scanning sensor SS to scan the region 1 to obtain a factor and determines a first set of values of a parameter 352 from the factor. As an example, the scanning sensor SS is associated with the coil 1 when the scanning sensor SS is controlled to scan the region 1. Also, the processor 116 controls the scanning sensor SS to scan the region n to obtain a factor and determines an n^{th} set of values of a parameter 354 from the factor. As an example, the scanning sensor SS is associated with the coil n when the scanning sensor SS is controlled to scan the region n.

The processor 116 compares each of the values of the first set of the parameter 352 for the region 1 with the predetermined parameter threshold range to determine whether the value falls within the predetermined parameter threshold range. Upon determining that the values of the parameter 352 for the region 1 are outside the predetermined parameter threshold range, the processor 116 controls one or more of the first through n^{th} RF generators or one or more of the first through n^{th} matchless plasma sources of the RF source system 102 (FIG. 1A) or one or more of the valves 1 through p (FIG. 1C) or a combination thereof until the values of the first set of the parameter 352 for the region 1 lie with the predetermined parameter threshold range. On the other hand, in response to determining that the values of the first set of the parameter 352 for the region 1 are within the predetermined parameter threshold range, the processor 116 does not control the RF source system 102 and does not control the valves 1 through p. When the RF source system 102 is not controlled, the RF signal 121₁ is not modified to the RF signal 124₁ (FIG. 1A) and the RF signal 121ₙ is not modified to the RF signal 124ₙ (FIG. 1A).

Also, the processor 116 compares each of the values of the n^{th} set of the parameter 354 for the region n with the predetermined parameter threshold range to determine whether the value falls within the predetermined parameter threshold range. Upon determining that the values of the n^{th} set of the parameter 354 for the region n are outside the predetermined parameter threshold range, the processor 116 controls one or more of the first through n^{th} RF generators or one or more of the first through n^{th} matchless plasma sources of the RF source system 102 (FIG. 1A) or one or more of the valves 1 through p (FIG. 1C) or a combination thereof until the values of the n^{th} set of the parameter 354 for the region n lie with the predetermined parameter threshold range. On the other hand, in response to determining that the values of the n^{th} set of the parameter 354 for the region n are within the predetermined parameter threshold range, the processor 116 does not control the RF source system 102 and does not control the valves 1 through p.

It should be noted that the processor 116 does not wait for an entire region, such as the region 1 or the region n, to be scanned by the scanning sensor SS before controlling the RF source system 102 or one or more of the valves 1 through p or a combination thereof to achieve uniformity across the top surface of the substrate 222 (FIG. 2B). For example, the first set of values of the parameter 352 is determined based on a scan of half of the region 1 and the n^{th} set of values of the parameter 354 is determined based on a scan of half of the region n. Because the processor 116 does not wait for the entire region to be scanned before controlling the RF source system 102 or one or more of the valves 1 through p or a combination thereof, the uniformity across the top surface of the substrate 222 is achieved in quasi real-time.

In one embodiment, the scanning sensor SS is located at a third horizontal level, which is about the first horizontal level of the coils 1 through n.

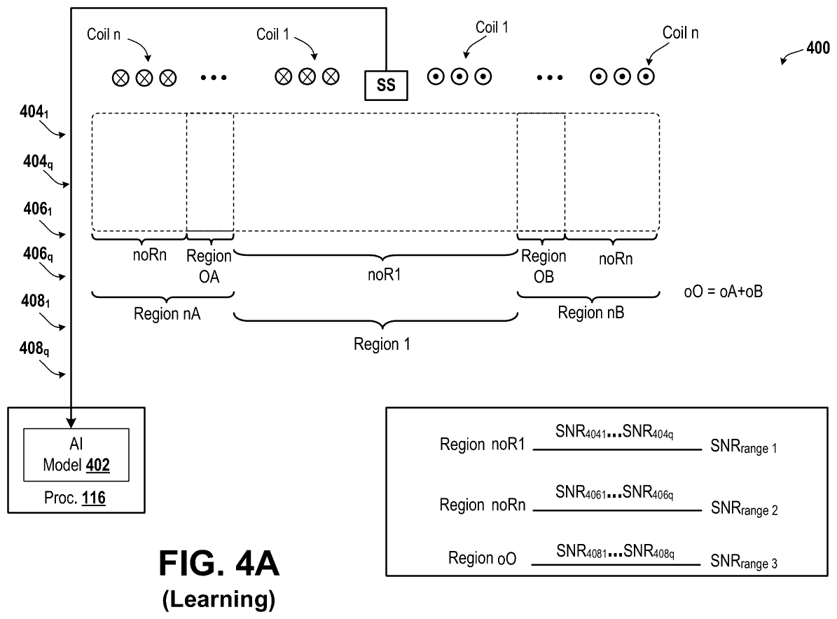

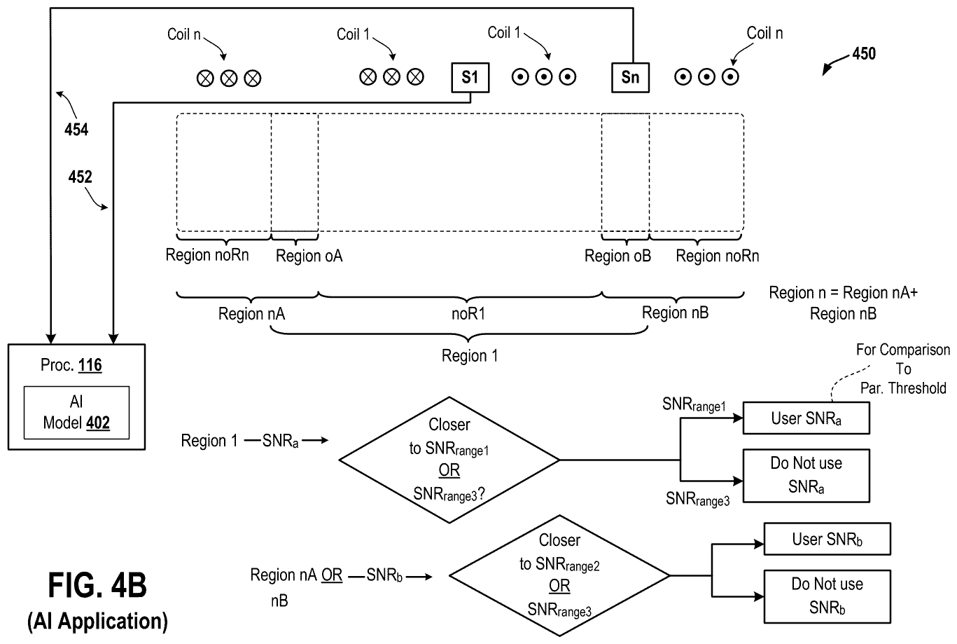

FIG. 4A is a diagram of an embodiment of a system 400 to illustrate learning by an artificial intelligence (AI) model 402 of signal-to-noise ratios (SNRs) associated with different regions within the inside volume of the plasma chamber 108 (FIG. 1A). An example of the AI model 402 is a machine learning model that learns based on patterns of data provided to the machine learning model. The system 400 includes the coils 1 through n, and the processor 116. The AI model 402 is implemented within the processor 116. For example, the processor 116 executes the AI model 402.

The processor 116 controls the scanning sensor SS to scan the regions noR1, oO, and nORn. For example, the processor 116 controls the scanning sensor SS to scan each of the regions noR1, oO, and nORn for a predetermined number of scans, such as q scans, where q is a positive integer. The predetermined number of scans is received from the user via the input device.

During a first one of the predetermined number of scans, the scanning sensor SS scans the region noR1 to output a sensor signal 404₁. The processor 116 determines the parameter from the factor of the sensor signal 404₁, and determines a signal-to-noise ratio SNR₄₀₄₁ of the parameter. For example, the processor 116 identifies an absolute maximum amplitude of the parameter determined based on the sensor signal 404₁. The absolute maximum amplitude is a maximum of all amplitudes of the parameter determined based on the sensor signal 404₁. Moreover, in the example, the processor 116 identifies that multiple oscillations of the parameter determined based on the sensor signal 404₁ have a local maximum amplitude that is below a predetermined limit. An example of the predetermined limit is a value from and including 5% to 10% of the absolute maximum amplitude. To illustrate, the predetermined limit is 10% or 5% of the absolute maximum amplitude. The predetermined limit is below the absolute maximum amplitude. The processor 116 calculates the signal-to-noise ratio SNR₄₀₄₁ as a ratio of the absolute maximum amplitude and the local maximum amplitude.

In a similar manner, during a q^{th} one of the predetermined number of scans, the scanning sensor SS scans the region noR1 to output a sensor signal 404_{q}. The processor 116 determines the parameter from the factor of the sensor signal 404_{q}, and determines a signal-to-noise ratio SNR_{404q} of the parameter. For example, the processor 116 identifies an absolute maximum amplitude of the parameter determined based on the sensor signal 404_{q}. The absolute maximum amplitude is a maximum of all amplitudes of the parameter determined based on the sensor signal 404_{q}. Moreover, in the example, the processor 116 identifies that multiple oscillations of the parameter determined based on the sensor signal 404_{q} have a local maximum amplitude that is below the predetermined limit. The predetermined limit is below the absolute maximum amplitude. The processor 116 calculates the signal-to-noise ratio SNR_{404q} as a ratio of the absolute maximum amplitude and the local maximum amplitude.

The processor 116 provides the signal-to-noise ratios SNR₄₀₄₁ through SNR_{404q} to the AI model 402 to train the AI model 402. For example, the processor 116 provides the signal-to-noise ratios SNR₄₀₄₁ through SNR_{404q} to the AI model 402 and at each time any of the signal-to-noise ratios SNR₄₀₄₁ through SNR_{404q} is provided to the AI model 402, the processor 116 indicates to the AI model 402 that the signal-to-noise ratio is for the region noR1 and to output that the signal-to-noise ratio is to be used.

The processor 116 determines that the signal-to-noise ratios SNR₄₀₄₁ through SNR_{404q} for the predetermined number of scans falls within a signal-to-noise ratio range SNR_{range1}. For example, the processor 116 determines that the signal-to-noise ratio SNR₄₀₄₁ has a lowest value among all values of signal-to-noise ratios determined from the predetermined number of scans and the signal-to-noise ratio SNR_{404q} has a highest value among all values of signal-to-noise ratios determined from the predetermined number of scans. In the example, the processor 116 further determines that the signal-to-noise ratio range SNR_{range1} extends from the signal-to-noise ratio SNR₄₀₄₁ to the signal-to-noise ratio SNR_{404q}.

Moreover, during a first one of the predetermined number of scans, the scanning sensor SS scans the region nORn to output a sensor signal 406₁. The processor 116 determines the parameter from the factor of the sensor signal 406₁, and determines a signal-to-noise ratio SNR₄₀₆₁ of the parameter in the same manner in which the processor 116 determines the signal-to-noise ratio SNR₄₀₄₁ of the parameter of the sensor signal 404₁ based on the parameter of the sensor signal 404₁.

In a similar manner, during a q^{th} one of the predetermined number of scans, the scanning sensor SS scans the region noRn to output a sensor signal 406_{q}. The processor 116 determines the parameter from the factor of the sensor signal 406_{q}, and determines a signal-to-noise ratio SNR_{406q} of the parameter in the same manner in which the processor 116 determines the signal-to-noise ratio SNR_{404q} of the parameter of the sensor signal 404_{q} based on the parameter of the sensor signal 404_{q}.

The processor 116 provides the signal-to-noise ratios SNR₄₀₆₁ through SNR_{406q} to the AI model 402 to train the AI model 402. For example, the processor 116 provides the signal-to-noise ratios SNR₄₀₆₁ through SNR_{406q} to the AI model 402 and at each time any of the signal-to-noise ratios SNR₄₀₆₁ through SNR_{406q} is provided to the AI model 402, the processor 116 indicates to the AI model 402 that the signal-to-noise ratio is for the region noRn and indicates to the AI model 402 to output that the signal-to-noise ratio is to be used.

The processor 116 determines that the signal-to-noise ratios SNR₄₀₆₁ through SNR_{406q} for the predetermined number of scans falls within a signal-to-noise ratio range SNR_{range2}. For example, the processor 116 determines that the signal-to-noise ratio SNR₄₀₆₁ has a lowest value among all values of signal-to-noise ratios determined from the predetermined number of scans and the signal-to-noise ratio SNR_{406q} has a highest value among all values of signal-to-noise ratios determined from the predetermined number of scans. In the example, the processor 116 further determines that the signal-to-noise ratio range SNR_{range2} extends from the signal-to-noise ratio SNR₄₀₆₁ to the signal-to-noise ratio SNR_{406q}.

Also, during a first one of the predetermined number of scans, the scanning sensor SS scans the region oO to output a sensor signal 408₁. The processor 116 determines the parameter from the factor of the sensor signal 408₁, and determines a signal-to-noise ratio SNR₄₀₈₁ of the parameter based on the parameter of the sensor signal 408₁ in the same manner in which the processor 116 determines the signal-to-noise ratio SNR₄₀₄₁ of the parameter of the sensor signal 4041 based on the parameter of the sensor signal 404₁.

In a similar manner, during a q^{th} one of the predetermined number of scans, the scanning sensor SS scans the region oO to output a sensor signal 408_{q}. The processor 116 determines the parameter from the factor of the sensor signal 408_{q}, and determines a signal-to-noise ratio SNR_{408q} of the sensor signal 408_{q} based on the sensor signal 408_{q} in the same manner in which the processor 116 determines the signal-to-noise ratio SNR_{404q} of parameter of the sensor signal 404_{q} based on the parameter of the sensor signal 404_{q}.

The processor 116 provides the signal-to-noise ratios SNR₄₀₈₁ through SNR_{408q} to the AI model 402 to train the AI model 402. For example, the processor 116 provides the signal-to-noise ratios SNR₄₀₈₁ through SNR_{408q} to the AI model 402 and at each time any of the signal-to-noise ratios SNR₄₀₈₁ through SNR_{408q} is provided to the AI model 402, the processor 116 indicates to the AI model 402 that the signal-to-noise ratio is for the region oO and to output that the signal-to-noise ratio is to be ignored.

The processor 116 determines that the signal-to-noise ratios SNR₄₀₈₁ through SNR_{408q} for the predetermined number of scans falls within a signal-to-noise ratio range SNR_{range3}. For example, the processor 116 determines that the signal-to-noise ratio SNR₄₀₈₁ has a lowest value among all values of signal-to-noise ratios determined from the predetermined number of scans and the signal-to-noise ratio SNR_{408q} has a highest value among all values of signal-to-noise ratios determined from the predetermined number of scans. In the example, the processor 116 further determines that the signal-to-noise ratio range SNR_{range3} extends from the signal-to-noise ratio SNR₄₀₈₁ to the signal-to-noise ratio SNR_{408q}.

In one embodiment, instead of the scanning sensor SS, the sensors S1 through Sn are used to scan the regions noR1, oO, and noRn.

FIG. 4B is a diagram of an embodiment of a system 450 to illustrate an application of the AI model 402 to determine whether to apply a value of a sensor signal received from any of the sensors S1 through Sn. The determination of whether to apply the value of the sensor signal is used to determine whether to control the RF source system 102 (FIG. 1A) or one or more of the valves 1 through p (FIG. 1C) to achieve the uniformity. The system 450 includes the coils 1 through n.

The sensor S1 scans at least a portion of the region 1 to output a sensor signal 452 to the processor 116. An example of the portion of the region 1 includes a portion of the region oA and a portion of the region noR1. Another example of the portion of the region 1 includes the region oA or the region noR1. The processor 116 calculates the parameter from the factor of the sensor signal 452. The processor 116 determines a signal-to-noise ratio SNRₐ of the parameter calculated based on the sensor signal 452. For example, the processor 116 identifies an absolute maximum amplitude of the parameter determined based on the sensor signal 452. In the example, the absolute maximum amplitude, which is a maximum of all amplitudes of the parameter determined based on the sensor signal 452, is a maximum signal amplitude. Moreover, in the example, the processor 116 identifies that multiple oscillations of the parameter determined based on the sensor signal 452 have a local maximum amplitude that is below a predetermined limit. An example of the predetermined limit is a value from and including 5% to 10% of the absolute maximum amplitude. To illustrate, the predetermined limit is 10% or 5% of the absolute maximum amplitude. The predetermined limit is below the absolute maximum amplitude. The processor 116 calculates the signal-to-noise ratio SNRₐ as a ratio of the absolute maximum amplitude and the local maximum amplitude.

The processor 116 provides the signal-to-noise ratio SNRₐ to the AI model 402. The AI model 402 determines whether the signal-to-noise ratio SNRₐ is similar to one of the signal-to-noise ratios SNR₄₀₄₁ through SNR_{404q} or one of the signal-to-noise ratios SNR₄₀₈₁ through SNR_{408q} (FIG. 4A). For example, the AI model 402 determines whether the signal-to-noise ratio SNRₐ falls within the signal-to-noise ratio range SNR_{range1} or SNR_{range3}. Upon determining that the signal-to-noise ratio SNRₐ falls within the signal-to-noise ratio range SNR_{range1}, the AI model 402 determines that the signal-to-noise ratio SNRₐ is similar to one of the signal-to-noise ratios SNR₄₀₄₁ through SNR_{404q}. On the other hand, upon determining the signal-to-noise ratio SNRₐ falls within the signal-to-noise ratio range SNR_{range3}, the AI model 402 determines that the signal-to-noise ratio SNRₐ is similar to one of the signal-to-noise ratios SNR₄₀₈₁ through SNR_{408q}.

As another example, the AI model 402 determines whether the signal-to-noise ratio SNRₐ is closer in value to one of the signal-to-noise ratios SNR₄₀₄₁ through SNR_{404q} compared to one of the signal-to-noise ratios SNR₄₀₈₁ through SNR_{408q}. Upon determining that the signal-to-noise ratio SNRₐ is closer in value to one of the signal-to-noise ratios SNR₄₀₄₁ through SNR_{404q}, the AI model 402 determines that the signal-to-noise ratio SNRₐ is similar to one of the signal-to-noise ratios SNR₄₀₄₁ through SNR_{404q}. On the other hand, in response to determining that the signal-to-noise ratio SNRₐ is closer in value to one of the signal-to-noise ratios SNR₄₀₈₁ through SNR_{408q}, the AI model 402 determines that the signal-to-noise ratio SNRₐis similar to one of the signal-to-noise ratios SNR₄₀₈₁ through SNR_{408q}.

Upon determining that the signal-to-noise ratio SNRₐ is similar to one of the signal-to-noise ratios SNR₄₀₄₁ through SNR_{404q}, the AI model 402 determines to use the parameter based on which the signal-to-noise ratio SNRₐ is determined to control the RF source system 102 or one of the valves 1 through p or a combination thereof to achieve the uniformity across the top surface of the substrate 222 (FIG. 2B). On the other hand, in response to determining that the signal-to-noise ratio SNRₐ is similar to one of the signal-to-noise ratios SNR₄₀₈₁ through SNR_{408q}, the AI model 402 determines to ignore the parameter having the signal-to-noise ratio SNRₐ and the parameter is not used to control the RF source system 102 or one of the valves 1 through p or a combination thereof.

Similarly, the sensor Sn scans at least a portion of the region n to output a sensor signal 454 to the processor 116. An example of the portion of the region n includes a portion of the region oA and a portion of the region noRn. Another example of the portion of the region n includes the region oA or the region oB or the region noRn. The processor 116 calculates the parameter from the factor of the sensor signal 454. The processor determines a signal-to-noise ratio SNR_{b}of the parameter calculated based on the sensor signal 454. For example, the processor 116 identifies an absolute maximum amplitude of the parameter determined based on the sensor signal 454. The absolute maximum amplitude, which is a maximum of all amplitudes of the parameter determined based on the sensor signal 454, is a maximum signal amplitude. Moreover, in the example, the processor 116 identifies that multiple oscillations of the parameter determined based on the sensor signal 454 have a local maximum amplitude that is below a predetermined limit. An example of the predetermined limit is a value from and including 5% to 10% of the absolute maximum amplitude. To illustrate, the predetermined limit is 10% or 5% of the absolute maximum amplitude. The predetermined limit is below the absolute maximum amplitude. The processor 116 calculates the signal-to-noise ratio SNR_{b} as a ratio of the absolute maximum amplitude and the local maximum amplitude.

The processor 116 provides the signal-to-noise ratio SNR_{b}to the AI model 402. The AI model 402 determines whether the signal-to-noise ratio SNR_{b} is similar to one of the signal-to-noise ratios SNR₄₀₆₁ through SNR_{406q} or one of the signal-to-noise ratios SNR₄₀₈₁ through SNR_{408q}. For example, the AI model 402 determines whether the signal-to-noise ratio SNR_{b} falls within the signal-to-noise ratio range SNR_{range2} or SNR_{range3}. Upon determining that the signal-to-noise ratio SNR_{b} falls within the signal-to-noise ratio range SNR_{range2}, the AI model 402 determines that the signal-to-noise ratio SNR_{b} is similar to one of the signal-to-noise ratios SNR₄₀₆₁ through SNR_{406q}. On the other hand, upon determining the signal-to-noise ratio SNR_{b} falls within the signal-to-noise ratio range SNR_{range3}, the AI model 402 determines that the signal-to-noise ratio SNR_{b} is similar to one of the signal-to-noise ratios SNR₄₀₈₁ through SNR_{408q}.

As another example, the AI model 402 determines whether the signal-to-noise ratio SNR_{b} is closer in value to one of the signal-to-noise ratios SNR₄₀₆₁ through SNR_{406q} compared to one of the signal-to-noise ratios SNR₄₀₈₁ through SNR_{408q}. Upon determining that the signal-to-noise ratio SNR_{b} is closer in value to one of the signal-to-noise ratios SNR₄₀₆₁ through SNR_{406q}, the AI model 402 determines that the signal-to-noise ratio SNR_{b} is similar to one of the signal-to-noise ratios SNR₄₀₆₁ through SNR_{406q}. On the other hand, in response to determining that the signal-to-noise ratio SNR_{b} is closer in value to one of the signal-to-noise ratios SNR₄₀₈₁ through SNR_{408q}, the AI model 402 determines that the signal-to-noise ratio SNR_{b} is similar to one of the signal-to-noise ratios SNR₄₀₈₁ through SNR_{408q}.

Upon determining that the signal-to-noise ratio SNR_{b} is similar to one of the signal-to-noise ratios SNR₄₀₆₁ through SNR_{406q}, the AI model 402 determines to use the parameter based on which the signal-to-noise ratio SNR_{b} is determined to control the RF source system 102 or one of the valves 1 through p or a combination thereof to achieve the uniformity across the top surface of the substrate 222 (FIG. 2B). On the other hand, in response to determining that the signal-to-noise ratio SNR_{b} is similar to one of the signal-to-noise ratios SNR₄₀₈₁ through SNR_{408q}, the AI model 402 determines to ignore the parameter based on which the signal-to-noise ratio SNR_{b} is determined and the parameter is not used to control the RF source system 102 or one of the valves 1 through p or a combination thereof.

In an embodiment, in the system 450, instead of the sensors S1 through Sn, the scanning sensor SS is used. In the embodiment, the AI model 402 determines whether to apply a value of a sensor signal received from the scanning sensor SS in the same manner, as that described above with reference to FIG. 4B, in which the AI model 402 determines whether to apply a value of a sensor signal received from any of the sensors S1 through Sn.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A plasma system comprising:
a radio frequency (RF) source system configured to generate a plurality of RF signals;
a plurality of RF antennas coupled to the RF source system to receive the plurality of RF signals, wherein the plurality of RF antennas includes a first antenna and a second antenna;
a processor coupled to the RF source system, wherein the processor is configured to:
determine a first parameter from one or more sensor signals received from one or more sensors associated with the first antenna;
determine a second parameter from the one or more sensor signals received from the one or more sensors associated with the second antenna;
determine whether the first parameter is within a predetermined parameter threshold range;
determine whether the second parameter is within the predetermined parameter threshold range; and
modify a variable of the RF source system when it is determined that the first parameter is outside the predetermined parameter threshold range or the second parameter is outside the predetermined parameter threshold range or a combination thereof, wherein the variable is modified to achieve uniformity across a surface of a substrate.

2. The plasma system of claim 1, wherein the second antenna surrounds the first antenna radially, wherein the one or more sensors include a plurality of sensors, wherein the plurality of sensors include a first sensor and a second sensor, wherein the first sensor is surrounded by the first antenna, and the second sensor is surrounded by the first antenna on one side and by the second antenna on an opposite side.

3. The plasma system of claim 1, wherein the plurality of RF antennas are configured to generate a plurality of electromagnetic fields within a plasma chamber, wherein the first parameter is temperature of electrons within a first region of the plasma chamber or density of plasma within the first region, wherein the second parameter is temperature of electrons within a second region of the plasma chamber or density of plasma within the second region.

4. The plasma system of claim 1, wherein the variable is power or frequency.

5. The plasma system of claim 1, wherein the RF source system includes a plurality of RF generators and a plurality of impedance matching circuits, or includes a plurality of matchless plasma source systems.

6. The plasma system of claim 1, wherein the substrate is a test substrate used to achieve the uniformity during processing of a substrate or a semiconductor wafer to achieve the uniformity in real-time.

7. The plasma system of claim 1, wherein the one or more sensors include beam sensors configured to be electronically controlled or include a scanning sensor that is configured to be mechanically controlled to scan in multiple directions within a plasma chamber.

8. A plasma system comprising:
a plurality of gas sources including a first gas source and a second gas source, wherein the first gas source is configured to store a first gas and the second gas source is configured to store a second gas;
a plurality of valve control systems, wherein the plurality of valve control systems include a first valve control system and a second valve control system;
a plurality of valves, wherein the plurality of valves include a first valve and a second valve, wherein the first valve is coupled to the first valve control system and to the first gas source and the second valve is coupled to the second valve control system and to the second gas source;
a plurality of radio frequency (RF) antennas configured to receive a plurality of RF signals, wherein the plurality of RF antennas includes a first antenna and a second antenna;
a processor coupled to the plurality of valve control systems, wherein the processor is configured to:
determine a first parameter from one or more sensor signals received from one or more sensors associated with the first antenna;
determine a second parameter from the one or more sensor signals received from the one or more sensors associated with the second antenna;
determine whether the first parameter is within a predetermined parameter threshold range;
determine whether the second parameter is within the predetermined parameter threshold range; and
modify one or more flow rates of one or more of the first and second gases when it is determined that the first parameter is outside the predetermined parameter threshold range or the second parameter is outside the predetermined parameter threshold range or a combination thereof.

9. The plasma system of claim 8, wherein the second antenna surrounds the first antenna radially, wherein the one or more sensors include a plurality of sensors, wherein the plurality of sensors include a first sensor and a second sensor, wherein the first sensor is surrounded by the first antenna, and the second sensor is surrounded by the first antenna on one side and by the second antenna on an opposite side.

10. The plasma system of claim 8, wherein the plurality of RF antennas are configured to generate a plurality of electromagnetic fields within a plasma chamber, wherein the first parameter is temperature of electrons within a first region of the plasma chamber or density of plasma within the first region, wherein the second parameter is temperature of electrons within a second region of the plasma chamber or density of plasma within the second region.

11. The plasma system of claim 8, wherein the variable is power or frequency.

12. The plasma system of claim 8, wherein the substrate is a test substrate used to achieve the uniformity during processing of a substrate or a semiconductor wafer to achieve the uniformity in real-time.

13. The plasma system of claim 8, wherein the one or more sensors include beam sensors configured to be electronically controlled or include a scanning sensor that is configured to be mechanically controlled to scan in multiple directions within a plasma chamber.

14. A plasma system comprising:
a radio frequency (RF) source system configured to generate a plurality of RF signals;
a plurality of RF antennas coupled to the RF source system to receive the plurality of RF signals, wherein the plurality of RF antennas includes a first antenna and a second antenna;
a plurality of gas sources including a first gas source and a second gas source, wherein the first gas source is configured to store a first gas and the second gas source is configured to store a second gas;
a plurality of valve control systems, wherein the plurality of valve control systems include a first valve control system and a second valve control system;
a plurality of valves, wherein the plurality of valves include a first valve and a second valve, wherein the first valve is coupled to the first valve control system and to the first gas source and the second valve is coupled to the second valve control system and to the second gas source;
a processor coupled to the RF source system and to the plurality of valve control systems, wherein the processor is configured to:
determine a first parameter from one or more sensor signals received from one or more sensors associated with the first antenna;
determine a second parameter from the one or more sensor signals received from the one or more sensors associated with the second antenna;
determine whether the first parameter is within a predetermined parameter threshold range;
determine whether the second parameter is within the predetermined parameter threshold range; and
modify a variable of the RF source system or one or more flow rates of one or more of the first and second gases or a combination thereof when it is determined that one of the first and second parameters is outside the predetermined parameter threshold range, wherein the variable or the one or more flow rates or the combination thereof is modified to achieve uniformity across a surface of a substrate.

15. The plasma system of claim 14, wherein the second antenna surrounds the first antenna, wherein the one or more sensors include a plurality of sensors, wherein the plurality of sensors include a first sensor and a second sensor, wherein the first sensor is surrounded by the first antenna, and the second sensor is surrounded by the first antenna on one side and by the second antenna on an opposite side.

16. The plasma system of claim 14, wherein the plurality of RF antennas are configured to generate a plurality of electromagnetic fields within a plasma chamber, wherein the first parameter is temperature of electrons within a first region of the plasma chamber or density of plasma within the first region, wherein the second parameter is temperature of electrons within a second region of the plasma chamber or density of plasma within the second region.

17. The plasma system of claim 14, wherein the variable is power or frequency.

18. The plasma system of claim 14, wherein the substrate is a test substrate used to achieve the uniformity during processing of a substrate or a semiconductor wafer to achieve the uniformity in real-time.

19. The plasma system of claim 14, wherein the one or more sensors include beam sensors configured to be electronically controlled or include a scanning sensor that is configured to be mechanically controlled to scan in multiple directions within a plasma chamber.

20. The plasma system of claim 14, wherein the RF source system includes a plurality of RF generators and a plurality of impedance matching circuits, or includes a plurality of matchless plasma source systems.
